(19) United States
(12) Patent Application Publication
(10) Pub. No.: US 2013/0008603 A1
(43) Pub. Date: Jan. 10, 2013

(54) COAXIAL CABLE AND SUBSTRATE PROCESSING APPARATUS

(75) Inventors: Hideo Eto, Mie (JP); Nobuyasu Nishiyama, Mie (JP); Makoto Saito, Mie (JP); Junko Ouchi, Mie (JP)

(73) Assignee: Kabushiki Kaisha Toshiba, Tokyo (JP)

(21) Appl. No.: 13/422,366

(22) Filed: Mar. 16, 2012

(30) Foreign Application Priority Data
Jul. 7, 2011 (JP) 2011-150613

(51) Int. Cl. H01B 11/18; C23C 16/52; C23C 16/509; B44C 1/22; H05H 1/24

(52) U.S. Cl. 156/345.27; 174/28; 156/345.44; 118/723 E; 118/696

(57) ABSTRACT

According to one embodiment, there is provided a coaxial cable that transmits radio frequency power. The coaxial cable includes an inner tube, an outer tube, and an insulating support member. The inner tube is made of a conductor. The outer tube is disposed outside the inner tube coaxially with the inner tube and is made of a conductor. The insulating support member is disposed between the inner tube and the outer tube. Cooling gas flows into at least one of a first space inside the inner tube and a second space between the inner tube and the outer tube.

### CROSS-REFERENCE TO RELATED APPLICATIONS

This application is based upon and claims the benefit of priority from Japanese Patent Application No. 2011-150613, filed on Jul. 7, 2011; the entire contents of which are incorporated herein by reference.

### FIELD

Embodiments described herein relate generally to a coaxial cable and a substrate processing apparatus.

### BACKGROUND

Recently, in a method of manufacturing a semiconductor device, a case of batch-processing a multilayer film in order for Quick Turnaround Time (QTAT) has been increasing. In particular, in an etching process using plasma, such as a Reactive Ion Etching (RIE) process, a case of batch-processing the multilayer film through continuous processing has been increasing. In the batch processing of the multilayer film, while continuing a plasma discharge, the continuous processing is performed by sequentially and continuously switching processing conditions, such as gas flow rate, pressure, temperature, and power, which are appropriate to each layer.

In the continuous processing, when a semiconductor substrate is processed, radio frequency power is transmitted through a coaxial cable to an electrode inside a processing chamber. In order to improve a processing rate of the continuous processing, it is necessary to increase a frequency of radio frequency power. If the frequency of the radio frequency power is increased, heat is generated due to radio frequency loss caused by a skin effect in the coaxial cable. Due to the increase in temperature caused by the heat, resistivity of an inner conductor of the coaxial cable is increased, and it is likely that the percentage of a heat loss rate of the radio frequency power will be increased. This tends to be difficult to transmit radio frequency power efficiently.

### BRIEF DESCRIPTION OF THE DRAWINGS

FIG. 1 is a diagram illustrating a configuration of a substrate processing apparatus, to which a coaxial cable according to an embodiment is applied;

FIGS. 2A and 2B are diagrams illustrating a configuration of a coaxial cable according to an embodiment;

FIGS. 3A to 3C are diagrams illustrating a flow of cooling gas according to an embodiment;

FIGS. 4A and 4B are diagrams illustrating a configuration of a hole of an inner tube according to an embodiment;

FIGS. 5A to 5E are diagrams illustrating a configuration of an insulating support member in a modified example of an embodiment; and

FIG. 6 is a diagram illustrating a configuration of a coaxial cable according to a comparative example.

### DETAILED DESCRIPTION

In general, according to one embodiment, there is provided a coaxial cable that transmits radio frequency power. The coaxial cable includes an inner tube, an outer tube, and an insulating support member. The inner tube is made of a conductor. The outer tube is disposed outside the inner tube coaxially with the inner tube and is made of a conductor. The insulating support member is disposed between the inner tube and the outer tube. Cooling gas flows into at least one of a first space inside the inner tube and a second space between the inner tube and the outer tube.

Exemplary embodiments of a coaxial cable and a substrate processing apparatus will be explained below in detail with reference to the accompanying drawings. The present invention is not limited to the following embodiments.

### Embodiment

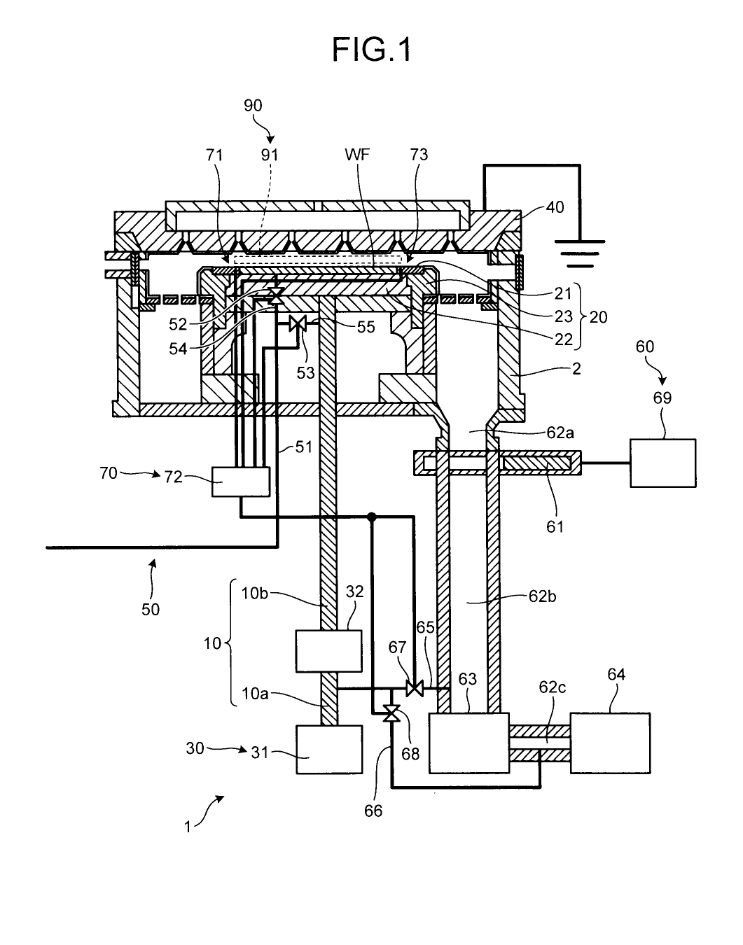

A substrate processing apparatus 1, to which a coaxial cable 10 according to an embodiment is applied, will be described with reference to FIG. 1. FIG. 1 is a diagram illustrating a configuration of the substrate processing apparatus 1, to which the coaxial cable 10 according to the embodiment is applied.

The substrate processing apparatus 1 is an apparatus configured to process a target substrate in a processing chamber 90. The substrate processing apparatus 1 may be a plasma processing apparatus such as, for example, an RIE apparatus or the like, and may be a deposition apparatus such as, for example, a CVD apparatus or the like. Hereinafter, the case that the substrate processing apparatus 1 is a plasma processing apparatus will be exemplarily described.

The substrate processing apparatus 1 includes the processing chamber 90, a lower electrode 20, a power supply controlling unit 30, a coaxial cable 10, an upper electrode 40, a cooling gas supply pipe 50, an exhaust controlling unit 60, and a temperature controlling unit 70.

The processing chamber 90 is a chamber configured to generate plasma inside, and is formed by a processing vessel 2. The processing vessel 2 is configured such that processing gas can be supplied from a gas supply controlling unit (not illustrated) to the processing chamber 90, and is also configured such that processing gas after the processing can be exhausted from the processing chamber 90 to the exhaust controlling unit 60.

The lower electrode 20 is disposed in a bottom side inside the processing chamber 90 such that the lower electrode 20 is insulated from the processing vessel 2 through an insulating material 23. A target substrate WF, such as a silicon wafer or the like, is placed on the lower electrode 20. The lower electrode 20 includes a temperature regulation stage 21 and an electrode 22. The temperature regulation stage 21 covers the electrode 22. In the temperature regulation stage 21, temperature is controlled by the temperature controlling unit 70. In this way, the temperature controlling unit 70 controls the temperature of the target substrate WF through the temperature regulation stage 21. The electrode 22 is supplied with power from the power supply controlling unit 30 through the coaxial cable 10, and supplies power to the target substrate WF through the temperature regulation stage 21. The temperature regulation stage 21 is made of, for example, a metal such as stainless steel, aluminum, or the like, alumina, or a ceramic such as yttria or the like. The electrode 22 is made of, for example, a metal such as stainless steel, aluminum, or the like.

In the power supply controlling unit 30, a matching circuit 32 matches an impedance of a radio frequency power supply 31 side with an impedance of the lower electrode 20 side. In a state where the matching is performed by the matching circuit 32, the radio frequency power is supplied from the radio frequency power supply 31 through the coaxial cable 10 to the lower electrode 20. If the upper electrode 40 is grounded and a radio frequency voltage is supplied to the lower electrode 20, the upper electrode 40 and the lower electrode 20 for plasma generation generate plasma inside the processing chamber 90. In other words, plasma is generated in a space 91 between the upper electrode 40 and the lower electrode 20. In this case, a sheath region having a potential gradient is also formed between the plasma region and the lower electrode 20, and ions (for example, F⁺, CF3⁺, or the like) generated together with radicals within the plasma are accelerated toward the surface of the target substrate WF (the lower electrode 20 side). In this way, an anisotropic etching process is carried out.

In addition, the radio frequency power supply 31 is disposed under the processing chamber 90. The matching circuit 32 is disposed under the processing chamber 90 and between the radio frequency power supply 31 and the lower electrode 20. For example, the matching circuit 32 is disposed on a straight line connecting the radio frequency power supply 31 and the lower electrode 20.

The coaxial cable 10 extends linearly from the radio frequency power supply 31 to the lower electrode 20. Accordingly, the coaxial cable 10 transmits the radio frequency power from the radio frequency power supply 31 to the lower electrode 20. The coaxial cable 10 includes a coaxial cable 10a and a coaxial cable 10b. The coaxial cable 10a extends linearly from the radio frequency power supply 31 to the matching circuit 32 such that the radio frequency power supply 31 and the matching circuit 32 are connected to each other. The coaxial cable 10b extends linearly from the matching circuit 32 to the lower electrode 20 such that the matching circuit 32 and the lower electrode 20 are connected to each other. The coaxial cable 10b and the coaxial cable 10a have the same internal configuration to be described later.

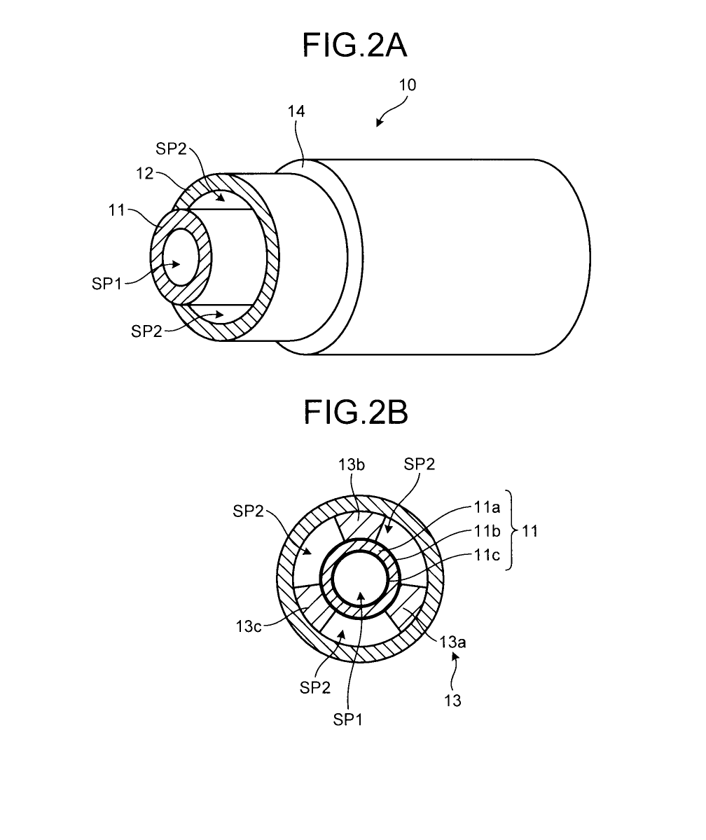

The cooling gas supply pipe 50 extends from a bottom of the processing chamber 90 to the lower electrode 20 such that cooling gas is supplied to the lower electrode 20. In addition, the cooling gas supply pipe 50 supplies the cooling gas to a first space SP1 and a second space SP2 (see FIG. 2A) inside the coaxial cable 10, which will be described later. Specifically, the cooling gas supply pipe 50 includes a main supply pipe 51, a supply pipe 54 for electrode, a supply pipe 55 for cable, an on-off valve 52, and an on-off valve 53. The on-off valve 52 and the on-off valve 53 are controlled by a temperature controller 72, which will be described later. The on-off valve 52 is opened at a predetermined timing, and the cooling gas supplied by the main supply pipe 51 is supplied through the supply pipe 54 for electrode to the lower electrode 20. Accordingly, the target substrate WF is cooled down. The on-off valve 53 is opened at a predetermined timing, and the cooling gas supplied by the main supply pipe 51 is supplied through the supply pipe 55 for cable to the first space SP1 and the second space SP2 inside the coaxial cable 10, which will be described later. In this way, a predetermined region inside the coaxial cable 10 is cooled down.

The exhaust controlling unit 60 controls a pressure of the processing chamber 90 and an exhaust amount of the processing gas. In addition, the exhaust controlling unit 60 controls the exhaust of the cooling gas from the first space SP1 and the second space SP2 inside the coaxial cable 10, which will be described later. Specifically, the exhaust controlling unit 60 includes a pressure sensor (not illustrated), exhaust pipes 62a to 62c, a gate valve 61, a turbo pump 63, a rotary pump 64, an exhaust pipe 65, an exhaust pipe 66, an on-off valve 67, an on-off valve 68, and a pressure controller 69. The pressure sensor detects a pressure inside the processing chamber 90, and supplies information on the pressure value to the pressure controller 69. The pressure controller 69 controls the degree of opening of the gate valve 61, depending on the pressure value supplied from the pressure sensor, such that the pressure inside the processing chamber 90 becomes a target value. In this way, the pressure of the processing chamber 90 and the exhaust amount of the processing gas are controlled.

In addition, the on-off valve 67 and the on-off valve 68 are controlled by the temperature controller 72 which will be described later. The on-off valve 67 is opened at a predetermined timing, and the cooling gas of the first space SP1 and the second space SP2 inside the coaxial cable 10 is exhausted through the exhaust pipe 65 to the exhaust pipe 62b. The on-off valve 68 is opened at a predetermined timing, and the cooling gas of the first space SP1 and the second space SP2 inside the coaxial cable 10 is exhausted through the exhaust pipe 66 to the exhaust pipe 62c. In addition, the exhaust pipe 62c is maintained in a vacuum state by the rotary pump 64, and the exhaust pipes 62a and 62b are maintained in a higher vacuum state than the exhaust pipe 62c by the turbo pump 63.

The temperature controlling unit 70 controls the temperature of the target substrate WF through the temperature regulation stage 21. Specifically, the temperature controlling unit 70 includes the temperature controller 72, and a temperature sensor 71 and a temperature regulator (heater or cooler) 73 disposed inside the temperature regulation stage 21. The temperature sensor 71 detects the temperature of the target substrate WF placed on the temperature regulation stage 21. The temperature sensor 71 supplies information on the detected temperature to the temperature controller 72. The temperature controller 72 controls the temperature regulator 73 such that the temperature of the target substrate WF becomes a predetermined target temperature. For example, if the target substrate WF needs to be cooled down to a predetermined target temperature, the temperature controller 72 sets a temperature by the temperature regulator (cooler) 73 disposed inside the temperature regulation stage 21, and opens the on-off valve 52 so that the target substrate WF is cooled down through the cooling gas supplied between the temperature regulation stage 21 and the target substrate WF. In this way, the temperature of the target substrate WF is controlled.

In addition, the temperature controlling unit 70 controls the temperature of the coaxial cable 10. Specifically, the temperature controller 72 of the temperature controlling unit 70 receives a notification that the radio frequency power supply 31 becomes a state that power should be supplied, from, for example, the radio frequency power supply 31, opens the on-off valve 53 to supply the cooling gas to the first space SP1 and the second space SP2 inside the coaxial cable 10, and also opens the on-off valve 67 or 68 to exhaust the cooling gas from the first space SP1 and the second space SP2 inside the coaxial cable 10. In this way, a predetermined region inside the coaxial cable 10 is cooled down.

In addition, the temperature controller 72 of the temperature controlling unit 70 receives a notification that the radio frequency power supply 31 completed the supply of power, from, for example, the radio frequency power supply 31, closes the on-off valve 53 to stop supplying the cooling gas to the first space SP1 and the second space SP2 inside the coaxial cable 10, and also closes the on-off valve 67 or 68 to stop exhausting the cooling gas from the first space SP1 and the second space SP2 inside the coaxial cable 10. In this way, the cooling of a predetermined region inside the coaxial cable 10 is completed.

Next, the configuration of the coaxial cable 10 will be described with reference to FIGS. 2A and 2B. FIG. 2A is a perspective view illustrating the configuration of the coaxial cable 10, and FIG. 2B is a cross-sectional view illustrating the configuration of the coaxial cable 10.

The coaxial cable 10 includes an inner tube 11, an outer tube 12, an insulating support member 13, and a protective coating 14. That is, each of the coaxial cable 10b and the coaxial cable 10a includes the inner tube 11, the outer tube 12, the insulating support member 13, and the protective coating 14.

The inner tube 11 functions as an inner conductor in the coaxial cable 10 and is a part through which the radio frequency power is transmitted. The inner tube 11 is made of a predetermined conductor. Specifically, a body 11a of the inner tube 11 is made of, for example, stainless steel such as SUS304, copper, or the like. In addition, a low-resistivity layer 11b is formed on an outer surface of the body 11a using a material (metal or intermetallic compound), which contains at least one of silver, copper, gold, and platinum as a main component, through plating, sputtering, deposition, or the like. A low-resistivity layer 11c is also formed on an inner surface of the body 11a using a material (metal or intermetallic compound), which contains at least one of copper, gold, and platinum as a main component, through plating, sputtering, deposition, or the like.

The outer tube 12 is disposed outside the inner tube 11. In addition, the outer tube 12 is disposed coaxially with the inner tube 11. That is, the coaxial cable 10 according to the embodiment, in general, has a double-pipe structure in which the inner tube 11 and the outer tube 12 extend coaxially. The outer tube 12 functions as an outer conductor in the coaxial cable 10 and is a part to which a ground potential is supplied. The outer tube 12 is made of a predetermined conductor. The outer tube 12 may be made of, for example, stainless steel such as SUS304 or the like, or may be made of copper, aluminum, or the like.

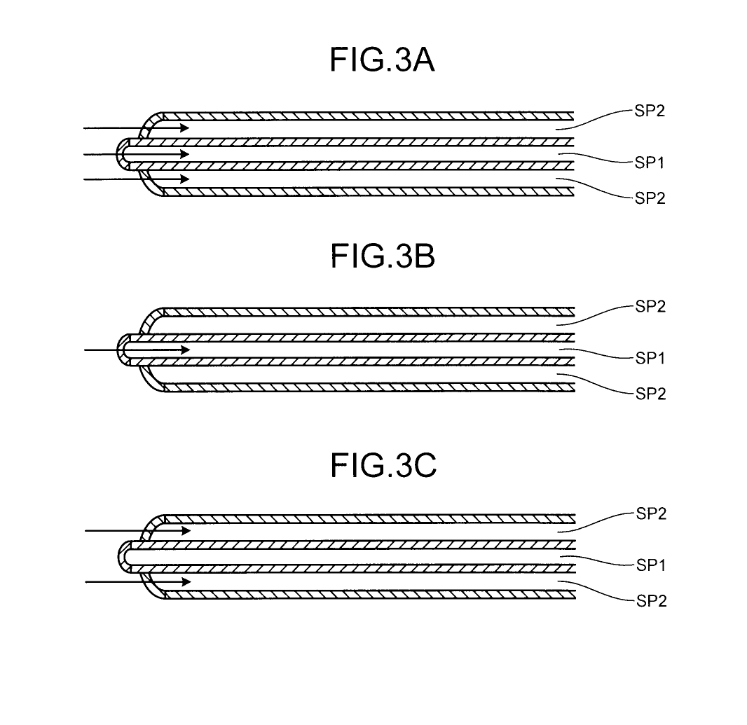

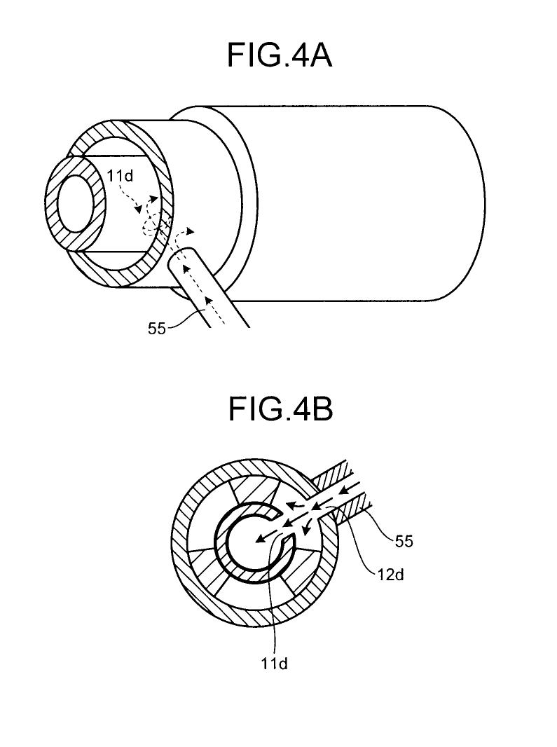

Herein, the cooling gas flows into the first space SP1 inside the inner tube 11 and the second space SP2 between the inner tube 11 and the outer tube 12 (see FIG. 3A). That is, the outer tube 12 includes a hole 12d at a position to which the supply pipe 55 for cable is connected (see FIGS. 4A and 4B). The inner tube 11 includes a hole lid corresponding to the hole 12d of the outer tube 12 (see FIGS. 4A and 4B). The hole 11d of the inner tube 11 communicates the first space SP1 with the second space SP2. The cooling gas flows into both the first space SP1 and the second space SP2 through the hole 11d. In addition, the outer tube 12 includes second holes (not illustrated) at positions to which the exhaust pipes 65 and 66 are connected. The inner tube 11 includes second holes corresponding to the second holes of the outer tube 12. The second holes of the inner tube 11 also communicate the first space SP1 with the second space SP2. The cooling gas is exhausted from both the first space SP1 and the second space SP2 through the second holes.

In addition, the first space SP1 of the coaxial cable 10b and the first space SP1 of the coaxial cable 10a are communicated with each other through a first communication passage penetrating the inside of the matching circuit 32. The second space SP2 of the coaxial cable 10b and the second space SP2 of the coaxial cable 10a are communicated with each other through a second communication passage penetrating the inside of the matching circuit 32.

The cooling gas flowing into the first space SP1 and the second space SP2 is, for example, a non-oxidizing gas having a thermal conductivity. The cooling gas includes, for example, helium gas or nitrogen gas. Since the helium gas has higher thermal conductivity and higher heat depriving property than the nitrogen gas, the helium gas is more suitable as the cooling gas than the nitrogen gas.

The insulating support member 13 is disposed between the inner tube 11 and the outer tube 12. Specifically, the insulating support member 13 supports the inner tube 11 and the outer tube 12 such that the cooling gas passes. That is, the insulating support member 13 includes a plurality of insulating support members 13a to 13c. The respective insulating support members 13a to 13c, when viewed in a cross section, cover a portion of the outer surface of the inner tube 11 and extend from the portion of the outer surface of the inner tube 11 to a portion of the inner surface of the outer tube 12. In this way, when viewed in the cross section, the cooling gas can pass through the second space SP2 corresponding to a portion of the outer surface of the inner tube 11 which is not covered by the insulating support members 13a to 13c. The insulating support member 13 is made of an insulating material so as to insulate the inner tube 11 from the outer tube 12 while supporting the inner tube 11 and the outer tube 12. The insulating support member 13 is made of, for example, polyethylene, ceramic, Teflon (registered trademark), Bakelite, or the like.

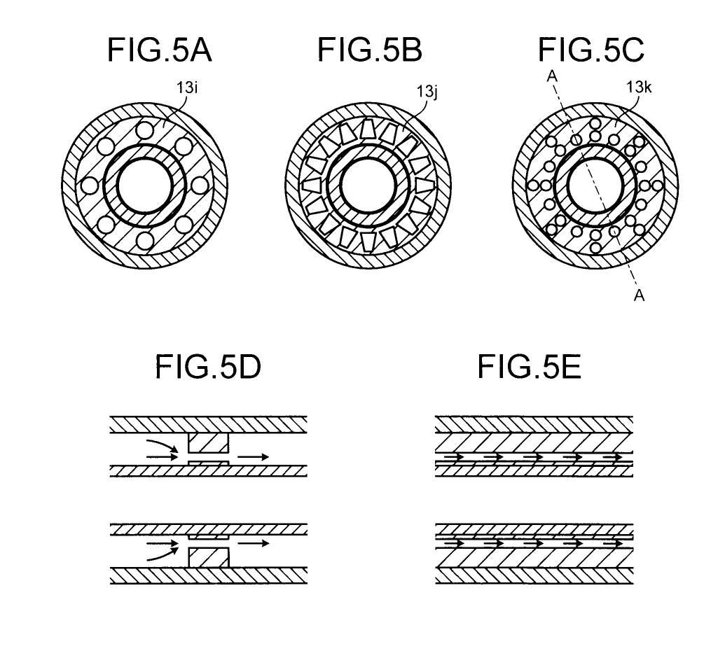

In addition, the insulating support member 13 may be disposed between the inner tube 11 and the outer tube 12 in a portion in a longitudinal direction of the inner tube 11 (see FIG. 5D), or may be disposed between the inner tube 11 and the outer tube 12 and extend in the longitudinal direction of the inner tube 11 (see FIG. 5E).

The protective coating 14 covers the outer surface of the outer tube 12. In this way, the protective coating 14 insulating-coats the outer tube 12 and also protects the outer tube 12 from outside air or the like. The protective coating 14 is made of, for example, an insulating material having a flame resistance, such as polyvinyl chloride, polyethylene, or the like.

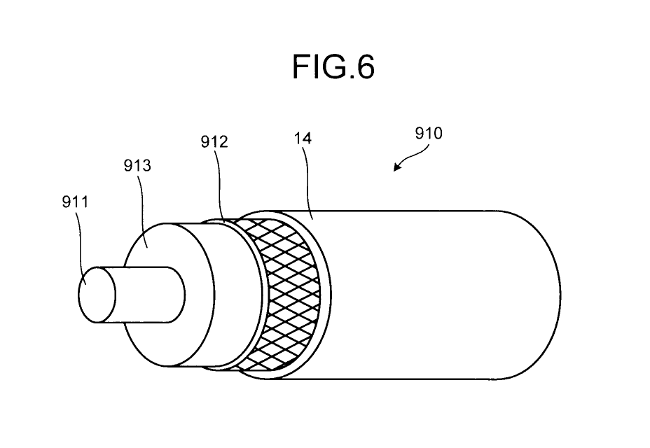

Herein, as illustrated in FIG. 6, in a coaxial cable 910, the case that an inner conductor 911 does not have the first space SP1 of the inside (see FIG. 2A) and a dielectric 913 is filled between the inner conductor 911 and an outer conductor 912 will be described. In this case, since it is difficult to cool the inner conductor 911, if a frequency of radio frequency power transmitted by the inner conductor 911 is increased (for example, to about 100 MHz), heat is generated by a radio frequency loss caused by a skin effect in the inner conductor 911. Due to the increase in temperature caused by the heat, the resistivity of the inner conductor 911 is increased, and it is likely that a heat loss percentage of the radio frequency power will be increased. This tends to be difficult to transmit the radio frequency power efficiently.

In contrast, in an embodiment, in the coaxial cable 10, the cooling gas flows into the first space SP1 inside the inner tube 11 and the second space SP2 between the inner tube 11 and the outer tube 12 (see FIG. 3A). In this way, the inner tube 11 functioning as the inner conductor in the coaxial cable 10 can be cooled from both the inside and the outside. Thus, when heat is generated by a radio frequency loss caused by a skin effect in the inner tube 11, the increase in temperature of the inner tube 11 can be suppressed. Since this can suppress the increase in the heat loss percentage of the radio frequency power, the radio frequency power can be efficiently transmitted.

Accordingly, since the radio frequency power can be efficiently transmitted with low loss, power usage necessary to realize a predetermined processing rate in the substrate processing apparatus 1, to which the coaxial cable 10 is applied, can be reduced.

In addition, in the coaxial cable 910 illustrated in FIG. 6, the dielectric 913 is filled between the inner conductor 911 and the outer conductor 912, and the outside of the outer conductor 912 is covered with the protective coating 14. Therefore, it is difficult to cool the outer conductor 912. For this reason, if the frequency of the radio frequency power transmitted by the inner conductor 911 is increased (for example, to about 100 MHz), heat is generated by radio frequency loss caused by a dielectric loss in the dielectric 913. It is likely that the heat will be transferred to the inner conductor 911. Due to the increase in temperature caused by the transferred heat, the resistivity of the inner conductor 911 increases, and it is likely that a heat loss percentage of the radio frequency power will increase. This tends to be difficult to transmit the radio frequency power efficiently.

In contrast, in an embodiment, in the coaxial cable 10, the cooling gas flows into the second space SP2 between the inner tube 11 and the outer tube 12 (see FIG. 3A). In this way, the inner tube 11 functioning as the inner conductor in the coaxial cable 10 can be cooled from the inside and the outside. Thus, when heat is generated by the radio frequency loss caused by the skin effect in the inner tube 11, the increase in temperature of the inner tube 11 can be suppressed. Since this can suppress the increase in the heat loss percentage of the radio frequency power, the radio frequency power can be efficiently transmitted.

In addition, in the coaxial cable 910 illustrated in FIG. 6, since the dielectric 913 is made of, for example, polyethylene foam or the like, and the inner conductor 911 is exposed to oxygen in the atmosphere, the surface of the inner conductor 911 is easy to oxidize. If the surface of the inner conductor 911 is oxidized, the resistivity of the inner conductor 911 is increased, and it is likely that the heat loss percentage of the radio frequency power will be increased. This tends to be difficult to transmit the radio frequency power efficiently.

In contrast, in an embodiment, the cooling gas flowing into the first space SP1 inside the inner tube 11 and the second space SP2 between the inner tube 11 and the outer tube 12 is a non-oxidizing gas. Since this can reduce the exposure of the inner and outer surfaces of the inner tube 11 to oxygen and the inner and outer surfaces of the inner tube 11 is difficult to oxidize, the increase in the resistivity of the inner tube 11 can be suppressed. Since this can suppress the increase in the heat loss percentage of the radio frequency power, the radio frequency power can be efficiently transmitted.

In addition, after the first space SP1 inside the inner tube 11 and the second space SP2 between the inner tube 11 and the outer tube 12 are held in a vacuum state for a predetermined time, the cooling gas may flow therein. In this case, since oxygen adsorbed on the surfaces of the inner tube 11 and the outer tube 12 is removed, the oxidation can be further suppressed than in the case where the cooling gas merely flows. The predetermined time is a time obtained experimentally in advance as a time enough to remove oxygen adsorbed on the surfaces of the inner tube 11 and the outer tube 12. Moreover, in this case, in the substrate processing apparatus 1, the turbo pump 63 exhausts the exhaust pipe 62b, also exhausts the first space SP1 and the second space SP2 inside the coaxial cable 10 through the exhaust pipe 62b and the exhaust pipe 65, and makes a high-vacuum state. When the cooling gas flows, the rotary pump 64 exhausts the exhaust pipe 62c and also exhausts the cooling gas existing in the first space SP1 and the second space SP2 inside the coaxial cable 10 through the exhaust pipe 62c and the exhaust pipe 66.

In addition, in the coaxial cable 910 illustrated in FIG. 6, since the surface of the inner conductor 911 is easy to oxidize, the inner conductor 911 tends to be easily degraded and the life span of the coaxial cable 10 including the inner tube 11 tends to be short.

In contrast, in an embodiment, since the inner and outer surfaces of the inner tube 11 are difficult to oxidize, the durability of the inner tube 11 can be improved, and the life span of the coaxial cable 10 including the inner tube 11 can be prolonged.

In addition, in an embodiment, the inner tube 11 includes a hole through which the first space SP1 is communicated with the second space SP2. In other words, the inner tube 11 includes a hole 11d corresponding to the second hole 12d of a position to which the supply pipe 55 for cable is connected in the outer tube 12, and second holes corresponding to the second holes of the positions to which the exhaust pipes 65 and 66 are connected in the outer tube 12 (see FIGS. 4A and 4B). All of the hole 11d and the second holes of the inner tube 11 communicate the first space SP1 with the second space SP2. This enables the cooling gas to flow into both the first space SP1 and the second space SP2, and enables the cooling gas to be exhausted from both the first space SP1 and the second space SP2. Therefore, the inner tube 11 and the outer tube 12 can be efficiently cooled.

In addition, in an embodiment, low-resistivity layers are formed on the inner and outer surfaces of the inner tube 11 using a material (metal or intermetallic compound), which contains at least one of silver, copper, gold, and platinum as a main component, through plating, sputtering, deposition, or the like. In other words, in the inner tube 11, the low-resistivity layer 11h is formed on the outer surface of the body 11a using a material (metal or intermetallic compound), which contains at least one of silver, copper, gold, and platinum as a main component, through plating, sputtering, deposition, or the like. The low-resistivity layer 11c is formed on the inner surface of the body 11a using a material (metal or intermetallic compound), which contains at least one of silver, copper, gold, and platinum as a main component, through plating, sputtering, deposition, or the like. Therefore, when the skin effect occurs in the inner tube 11, the resistivity of the position to which the radio frequency power is transmitted can be reduced, and the body 11a, which is a major part of the inner tube 11, can be made of an inexpensive conductor material (for example, stainless steel such as SUS304 or the like). In addition, the outer tube 12, the insulating support member 13, and the protective coating 14 can also be made of an inexpensive material. This enables the coaxial cable 10 to be formed at a low cost.

Furthermore, in an embodiment, the temperature controller 72 of the temperature controlling unit 70 performs the cooling of the first space SP1 and the second space SP2 inside the coaxial cable 10 in a period during which power is supplied from the radio frequency power supply 31 to the lower electrode 20, and does not perform the cooling of the first space SP1 and the second space SP2 inside the coaxial cable 10 in a period during which no power is supplied from the radio frequency power supply 31 to the lower electrode 20. This can reduce the running cost of the cooling gas. Moreover, if the cooling gas is circulated, the running cost of the cooling gas can be further reduced.

In addition, in an embodiment, in the substrate processing apparatus 1, the cooling gas supply pipe 50 supplies the cooling gas between the temperature regulation stage 21 and the target substrate WF, and also supplies the cooling gas to the first space SP1 and the second space SP2 inside the coaxial cable 10. In other words, the cooling gas supply pipe 50 configured to supply the cooling gas between the temperature regulation stage 21 and the target substrate WF can also be used as a supply pipe configured to supply the cooling gas to the first space SP1 and the second space SP2 inside the coaxial cable 10. Therefore, the coaxial cable 10 can be applied to the substrate processing apparatus 1 at a low cost.

Furthermore, in an embodiment, in the substrate processing apparatus 1, the turbo pump 63 exhausts the exhaust pipe 62b and also exhausts the first space SP1 and the second space SP2 inside the coaxial cable 10 through the exhaust pipe 62b and the exhaust pipe 65. In addition, the rotary pump 64 exhausts the exhaust pipe 62c and also exhausts the first space SP1 and the second space SP2 inside the coaxial cable 10 through the exhaust pipe 62c and the exhaust pipe 66. In other words, the turbo pump 63 configured to exhaust the exhaust pipe 62b can also be used as a turbo pump configured to exhaust the first space SP1 and the second space SP2 inside the coaxial cable 10. The rotary pump 64 configured to exhaust the exhaust pipe 62c can also be used as a rotary pump configured to exhaust the first space SP1 and the second space SP2 inside the coaxial cable 10. For this point of view, the coaxial cable 10 can also be applied to the substrate processing apparatus 1 at a low cost.

In addition, the cooling gas, as illustrated in FIGS. 3B and 3C, may flow into at least one of the first space SP1 and the second space SP2 inside the coaxial cable 10.

For example, as illustrated in FIG. 3B, the cooling gas may flow into the first space SP1, and the second space SP2 may be in the vacuum state. In this case, since the outside of the inner tube 11 is in the vacuum state, discharge occurring between the inner tube 11 and the outer tube 12 can be suppressed. In addition, exposure of the outer surface to oxygen can be reduced. Since the outer surface of the inner tube 11 is difficult to oxidize, the increase in the resistivity of the inner tube 11 can be suppressed, and also, the durability of the inner tube 11 and the outer tube 12 can be improved.

Alternatively, for example, as illustrated in FIG. 3C, the cooling gas may flow into the second space SP2, and the first space SP1 may be in the vacuum state. In this case, since the inner tube 11 is cooled from the outside of the inner tube 11 and the outer tube 12 is cooled from the inside of the outer tube 12, the increase in the temperature of the inner tube 11 can be suppressed. In addition, since the inside of the inner tube 11 is in the vacuum state, exposure of the inner surface of the inner tube 11 to oxygen can be reduced. Since the inner surface of the inner tube 11 is difficult to oxidize, the increase in the resistivity of the inner tube 11 can be suppressed, and also, the durability of the inner tube 11 can be improved.

In addition, in the case that the cooling gas flows into at least the second space SP2 (the case of FIG. 3A or 3C), the insulating support member 13, as illustrated in FIGS. 5A to 5C, may further include a plurality of holes through which the cooling gas passes.

For example, as illustrated in FIG. 5A, an insulating support member 13i may support not three points but entirety, and the holes may be arranged like a lotus root. This enables the cooling gas to uniformly flow, and enables the inner tube 11 and the outer tube 12 to be uniformly cooled.

Alternatively, for example, as illustrated in FIG. 5B, in each insulating support member of an insulating support member 13j, the width of the inner tube 11 side of each hole may be wider than the width of the outer tube 12 side. This enables the cooling gas to preferentially flow into the inner tube 11 side rather than the outer tube 12 side in the second space SP2.

Alternatively, for example, as illustrated in FIG. 5C, in each insulating support member of an insulating support member 13k, the number of holes disposed in the inner tube 11 side (for example, 16) may be greater than the number of holes disposed in the outer tube 12 side (for example, 8). This enables the cooling gas to preferentially flow into the inner tube 11 side rather than the outer tube 12 side in the second space SP2.

Moreover, the insulating support member may be disposed between the inner tube 11 and the outer tube 12 in a portion in the longitudinal direction of the inner tube 11, or the insulating support member may be disposed between the inner tube 11 and the outer tube 12 and extend in the longitudinal direction of the inner tube 11. In this case, each of the plurality of holes inside the insulating support member may be disposed in the inner tube 11 side.

For example, as illustrated in FIG. 5D, which is an A-A cross-section of FIG. 5C, when the insulating support member 13k is disposed between the inner tube 11 and the outer tube 12 in a portion in the longitudinal direction of the inner tube 11, the cooling gas having progressed the outer tube 12 side, as well as the cooling gas having progressed the inner tube 11 side in the second space SP2, can be guided to progress the inner tube 11 side in the second space SP2.

Alternatively, for example, as illustrated in FIG. 5E, which is the A-A cross-section of FIG. 5C, when the insulating support member 13k is disposed between the inner tube 11 and the outer tube 12 and extends in the longitudinal direction of the inner tube 11, the cooling gas progressing the inside of the insulating support member 13k can be guided to progress the inner tube 11 side in the second space SP2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A coaxial cable that transmits radio frequency power, comprising:
an inner tube made of a conductor;
an outer tube disposed outside the inner tube coaxially with the inner tube and made of a conductor; and
an insulating support member disposed between the inner tube and the outer tube,
wherein cooling gas flows into at least one of a first space inside the inner tube and a second space between the inner tube and the outer tube.

2. The coaxial cable according to claim 1,
wherein the cooling gas flows into at least the second space, and
the insulating support member supports the inner tube and the outer tube such that the cooling gas passes therethrough.

3. The coaxial cable according to claim 2,
wherein the insulating support member includes a plurality of holes through which the cooling gas passes.

4. The coaxial cable according to claim 3,
wherein each of the plurality of holes is disposed in the inner tube side.

5. The coaxial cable according to claim 3,
wherein in each of the plurality of holes, a width of a portion of the inner tube side is wider than a width of a portion of the outer tube side.

6. The coaxial cable according to claim 3,
wherein, in the insulating support member, number of holes disposed in the inner tube side is greater than number of holes disposed in the outer tube side.

7. The coaxial cable according to claim 1,
wherein the cooling gas flows into one of the first space and the second space, and
the other one of the first space and the second space is in a vacuum state.

8. The coaxial cable according to claim 7,
wherein the cooling gas flows into the first space, and
the second space is in a vacuum state.

9. The coaxial cable according to claim 1,
wherein the inner tube includes a hole through which the first space is communicated with the second space, and
the cooling gas flows into both the first space and the second space through the hole.

10. The coaxial cable according to claim 1,
wherein the cooling gas is non-oxidizing gas.

11. The coaxial cable according to claim 10,
wherein the cooling gas includes helium gas.

12. The coaxial cable according to claim 10,
wherein the cooling gas includes nitrogen gas.

13. The coaxial cable according to claim 1,
wherein a low-resistivity layer is formed on inner and outer surfaces of the inner tube using a material which contains at least one of silver, copper, gold, and platinum as a main component.

14. A substrate processing apparatus that processes a substrate within a processing chamber, comprising:
an electrode on which the substrate is placed within the processing chamber;
a radio frequency power supply disposed under the processing chamber and configured to supply radio frequency power to the electrode;
a coaxial cable of claim 1, which extends linearly from the radio frequency power supply to the electrode; and
a cooling gas supply pipe extending from a bottom of the processing chamber to the electrode such that cooling gas is supplied to the electrode,
wherein the cooling gas supply pipe further supplies the cooling gas to at least one of a first space inside the inner tube and a second space between the inner tube and the outer tube.

15. The substrate processing apparatus according to claim 14,
wherein the outer tube is supplied with a ground potential, and
the inner tube transmits radio frequency power supplied from the radio frequency power supply to the electrode.

16. The substrate processing apparatus according to claim 14, further comprising:
a temperature controlling unit configured to perform control such that the cooling gas is supplied to at least one of the first space and the second space in a period during which the radio frequency power is supplied from the radio frequency power supply to the electrode, and the cooling gas is not supplied to at least one of the first space and the second space in a period during which no radio frequency power is supplied from the radio frequency power supply to the electrode.

17. The substrate processing apparatus according to claim 14, further comprising:
an exhaust system configured to exhaust the inside of the processing chamber and also exhaust the first space and the second space.

18. The substrate processing apparatus according to claim 14,
wherein, after the first space and the second space are held in a vacuum state for a predetermined time, the cooling gas is introduced into at least one of the first space and the second space.

19. The substrate processing apparatus according to claim 18,
wherein, after both the first space and the second space are held in a vacuum state for a predetermined time, the cooling gas flows into one of the first space and the second space.

20. The substrate processing apparatus according to claim 18,
wherein, after both the first space and the second space are held in a vacuum state for a predetermined time, the cooling gas flows into both the first space and the second space.
